(19) United States
(12) Patent Application Publication
(10) Pub. No.: US 2026/0357409 A1
(43) Pub. Date: Nov. 12, 2026

(54) DEPOSITION MASK, METHOD OF MANUFACTURING THE SAME, AND ELECTRONIC DEVICE MANUFACTURED USING THE SAME

(71) Applicant: Samsung Display Co., LTD., Yongin-si (KR)

(72) Inventors: JIHYE HAN, Yongin-si (KR); CHULMIN BAE, Yongin-si (KR)

(21) Appl. No.: 19/634,238

(22) Filed: Mar. 31, 2026

(30) Foreign Application Priority Data
May 9, 2025 (KR) 10-2025-0060706

(51) Int. Cl. C23C 14/04; H10K 59/12; H10K 59/123; H10K 71/16

(52) U.S. Cl. CPC C23C 14/042; H10K 59/1201; H10K 59/123; H10K 71/166

(57) ABSTRACT

A deposition mask includes a mask substrate including an opening, and a mask pattern disposed on the mask substrate, where the mask pattern includes a first insulating layer disposed on the mask substrate, a second insulating layer disposed on the first insulating layer, and a plurality of hole patterns that overlap the opening and penetrate through the first insulating layer and the second insulating layer, and a cross-section of the mask pattern has a reverse taper shape of which a width in a first direction increases from a rear surface of the mask pattern, the rear surface being disposed next (adjacent) to the mask substrate, toward a top surface of the mask pattern opposite to the rear surface.

### CROSS REFERENCE TO RELATED APPLICATIONS

This application claims priority to Korean Patent Application No. 10-2025-0060706, filed on May 9, 2025, and all the benefits accruing therefrom under 35 U.S.C. §119, the content of which in its entirety is herein incorporated by reference.

### BACKGROUND

### 1. Field

Embodiments of the disclosure relate to a deposition mask, a method of manufacturing the same, and an electronic device manufactured using the same.

### 2. Description of the Related Art

An electronic device including a display panel includes a plurality of pixels. Each of the pixels includes a driving element such as a thin-film transistor and a display element such as an organic light-emitting diode (“OLED”). The display element may be formed by stacking electrodes, a plurality of organic layers, and a plurality of inorganic layers on a substrate.

Electrodes, a plurality of organic layers, a plurality of inorganic layers, and the like that are included in the display element may be formed on a substrate via deposition patterns formed in a certain area of the substrate through a deposition process. A deposition pattern may be formed using a mask in which openings are defined in certain areas.

As display panels using organic light-emitting diodes have recently advanced to relatively high resolution, the mask pattern of a mask for implementing such panels must also be fabricated in an ultra-small size on the micrometer scale. Accordingly, various studies are being conducted on technologies for manufacturing masks having fine patterns.

### SUMMARY

Provided are a deposition mask and a method of manufacturing the same, which are capable of improving deposition precision in a deposition process.

Provided is an electronic device in which display quality is improved by enhancing deposition precision.

However, these objects are exemplary and the scope of the disclosure is not limited thereby.

An embodiment of the disclosure provides a deposition mask including a mask substrate including an opening; and a mask pattern disposed on the mask substrate, where the mask pattern includes a first insulating layer disposed on the mask substrate, a second insulating layer disposed on the first insulating layer, and a plurality of hole patterns that overlap the opening and penetrate through the first insulating layer and the second insulating layer, and a cross-section of the mask pattern has a reverse taper shape of which a width in a first direction increases from a rear surface of the mask pattern, the rear surface being disposed next (adjacent) to the mask substrate, toward a top surface of the mask pattern opposite to the rear surface.

In an embodiment of the disclosure, the second insulating layer may be formed by a deposition process different from the deposition process used to form the first insulating layer.

In an embodiment of the disclosure, the second insulating layer may be deposited at a higher temperature than that for the first insulating layer.

In an embodiment of the disclosure, the first insulating layer may be deposited by plasma-enhanced chemical vapor deposition, and the second insulating layer may be deposited by low-pressure chemical vapor deposition.

In an embodiment of the disclosure, the density of the first insulating layer may be lower than the density of the second insulating layer.

In an embodiment of the disclosure, an etch rate of the first insulating layer may be greater than an etch rate of the second insulating layer.

In an embodiment of the disclosure, the first insulating layer or the second insulating layer may include silicon nitride (SiNₓ).

In an embodiment of the disclosure, the mask pattern may further include at least one of a first carbon layer between the first insulating layer and the second insulating layer or a second carbon layer on the second insulating layer.

In an embodiment of the disclosure, the first carbon layer or the second carbon layer may include amorphous carbon.

In an embodiment of the disclosure, the first carbon layer or the second carbon layer may have a thickness less than the thickness of the first insulating layer.

An embodiment of the disclosure provides a method of manufacturing a deposition mask, including the steps of forming a first preliminary insulating layer on a mask substrate, forming a second preliminary insulating layer on the first preliminary insulating layer, forming a plurality of hole patterns penetrating through the first preliminary insulating layer and the second preliminary insulating layer, and forming an opening in the mask substrate so as to overlap the plurality of hole patterns, where a cross-section of each of the plurality of hole patterns has a positive taper shape of which a width in a first direction decreases from the first preliminary insulating layer toward the second preliminary insulating layer.

In an embodiment of the disclosure, the forming the second preliminary insulating layer may use a deposition process different from the deposition process used for the forming the first preliminary insulating layer.

In an embodiment, in another embodiment of the disclosure, the first preliminary insulating layer may be deposited by plasma-enhanced chemical vapor deposition, and the second preliminary insulating layer may be deposited by low-pressure chemical vapor deposition.

In an embodiment of the disclosure, the forming the second preliminary insulating layer may include using the same deposition process as that used for the forming the first preliminary insulating layer.

In an embodiment of the disclosure, the first preliminary insulating layer and the second preliminary insulating layer may be selectively etched by the same etching material, and an etch rate of the first preliminary insulating layer with respect to the etching material may be greater than an etch rate of the second preliminary insulating layer with respect to the etching material.

In an embodiment, in another embodiment of the disclosure, the first preliminary insulating layer or the second preliminary insulating layer may include silicon nitride (SiNₓ).

In an embodiment, in another embodiment of the disclosure, the method may further include, prior to the forming the second preliminary insulating layer, forming a preliminary carbon layer on the first preliminary insulating layer, where the forming the plurality of hole patterns may include selectively etching the first preliminary insulating layer, the preliminary carbon layer, and the second preliminary insulating layer to form the plurality of hole patterns.

In an embodiment, in another embodiment of the disclosure, the method may further include, prior to the forming the plurality of hole patterns, forming a preliminary carbon layer on the second preliminary insulating layer, where the forming the plurality of hole patterns may include selectively etching the first preliminary insulating layer, the preliminary carbon layer, and the second preliminary insulating layer to form the plurality of hole patterns.

In an embodiment of the disclosure, the method may further include, prior to the forming the second preliminary insulating layer, forming a first preliminary carbon layer on the first preliminary insulating layer, and, prior to the forming the plurality of hole patterns, forming a second preliminary carbon layer on the second preliminary insulating layer, where the forming the plurality of hole patterns may include selectively etching the first preliminary insulating layer, the first preliminary carbon layer, the second preliminary insulating layer, and the second preliminary carbon layer to form the plurality of hole patterns.

In an embodiment of the disclosure provides an electronic device including a substrate, a plurality of thin-film transistors arranged on the substrate, a plurality of pixel electrodes electrically connected to the thin-film transistors, a plurality of intermediate layers arranged on the pixel electrodes, and an opposite electrode disposed on the intermediate layers, where at least one of the thin-film transistors, the pixel electrodes, the intermediate layers, or the opposite electrode is formed using the deposition mask described above.

Other features and advantages other than those described above will become apparent from the following drawings, claims and detailed description of the disclosure.

### BRIEF DESCRIPTION OF THE DRAWINGS

These and/or other features will become apparent and more readily appreciated from the following description of the embodiments, taken in conjunction with the accompanying drawings in which:

FIG. 1 is a schematic cross-sectional view of an embodiment of an apparatus for manufacturing a display device of the disclosure;

FIG. 2 is a schematic plan view of an embodiment of a deposition mask of the disclosure;

FIG. 3 is a schematic cross-sectional view of a deposition mask taken along line I-I' of FIG. 2;

FIG. 4 is an enlarged view of area AA of FIG. 3;

FIG. 5 is a schematic cross-sectional view of an embodiment of a deposition mask of the disclosure;

FIG. 6 is a schematic cross-sectional view of an embodiment of a deposition mask of the disclosure;

FIG. 7 is a schematic cross-sectional view of an embodiment of a deposition mask of the disclosure;

FIGS. 8-13 are schematic cross-sectional views illustrating an embodiment of a method of manufacturing a deposition mask of the disclosure;

FIG. 14 is a schematic perspective view of an embodiment of a display device of the disclosure;

FIG. 15 is a schematic cross-sectional view of an embodiment of a display device of the disclosure;

FIG. 16 is an equivalent circuit diagram of an embodiment of a pixel included in a display device of the disclosure;

FIG. 17 is a schematic cross-sectional view of an embodiment of a display device of the disclosure;

FIG. 18 is a block diagram illustrating an embodiment of an electronic device of the disclosure; and

FIG. 19 illustrates schematic diagrams of embodiments of electronic devices of the disclosure.

### DETAILED DESCRIPTION

As the disclosure allows for various changes and numerous embodiments, particular embodiments will be shown in the drawings and described in detail in the written description. The effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

It will be understood that although the terms "first," "second," etc., may be used herein to describe various components, these components should not be limited by these terms. These terms are only used to distinguish one component from another.

As used herein, the singular forms "a" and "an" are intended to include the plural forms as well, unless the context clearly indicates otherwise.

It will be further understood that the terms "comprises/includes" and/or "comprising/including" used herein specify the presence of stated features or components, but do not preclude the presence or addition of one or more other features or components.

It will be understood that when a unit, region, or component is referred to as being "formed on" another layer, region, or component, it can be directly or indirectly formed on the other layer, region, or component, and intervening units, regions, or components may be present.

In the drawings, the sizes of components may be exaggerated or reduced for convenience of explanation. In other words, since sizes and thicknesses of components in the drawings are arbitrarily illustrated for convenience of explanation, the following embodiments are not limited thereto.

Spatially relative terms, such as "above," "upper," "below," "beneath," "lower," or the like, may be used herein for ease of description to describe one element's relationship to another element(s) as illustrated in the drawings, and do not limit the direction in which each element is disposed.

It is to be understood that a specific process order may be performed differently from the described order. For example, two consecutively described processes may be performed substantially at the same time or performed in an order opposite to the described order.

Hereinafter, reference will now be made in detail to examples with reference to the accompanying drawings, where like reference numerals refer to like elements throughout and redundant descriptions thereof are omitted.

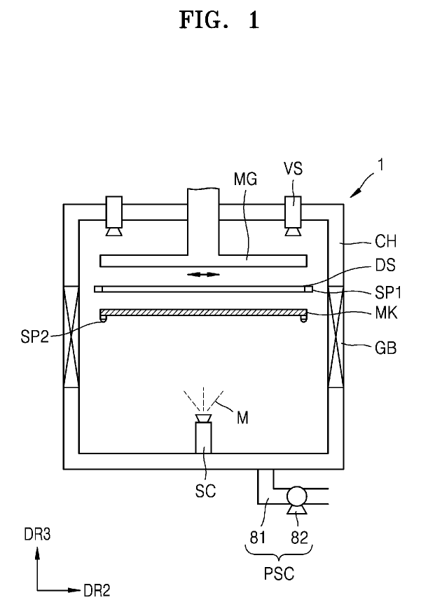

FIG. 1 is a schematic cross-sectional view of an embodiment of an apparatus for manufacturing a display device of the disclosure.

An apparatus 1 for manufacturing a display device may include a chamber CH, a first support SP1, a second support SP2, a deposition mask MK, a deposition source SC, a magnetic force portion MG, a vision portion VS, and a pressure controller PSC.

The chamber CH may have a space formed therein, and a display substrate DS and the deposition mask MK may be housed therein. In an embodiment, a portion of the chamber CH may be open, and a gate valve GB may be installed at the open portion of the chamber CH. Here, the open portion of the chamber CH may be opened or closed depending on the operation of the gate valve GB.

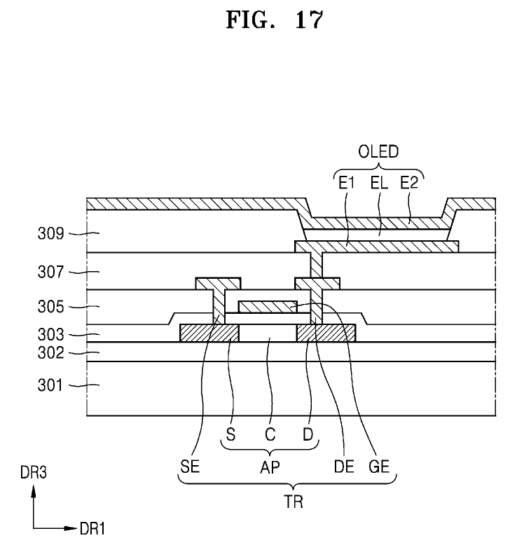

In an embodiment, the display substrate DS may refer to a display substrate DS in the process of manufacturing a display device, in which at least one of an organic layer, an inorganic layer, or a metal layer is deposited on a substrate (301, refer to FIG. 17), as will be described below. In an alternative embodiment, the display substrate DS may be a substrate on which none of the organic layer, inorganic layer, or metal layer has yet been deposited.

The first support SP1 may support the display substrate DS. In an embodiment, the first support SP1 may be in the form of a fixed plate disposed inside the chamber CH. In another embodiment, the first support SP1 may be in the form of a shuttle on which the display substrate DS is seated and that is linearly movable within the chamber CH. In another embodiment, the first support SP1 may include an electrostatic chuck or an adhesive chuck that is fixed to the chamber CH or disposed in the chamber CH so as to be movable within the chamber CH.

The second support SP2 may support the deposition mask MK. In an embodiment, the second support SP2 may be placed inside the chamber CH. The second support SP2 may finely adjust the position of the deposition mask MK. To this end, the second support SP2 may be provided with a separate drive unit or alignment unit to move the deposition mask MK in different directions.

In another embodiment, the second support SP2 may be in the form of a shuttle. In such a case, the second support SP2 may have the deposition mask MK seated thereon and may transport the deposition mask MK. In an embodiment, the second support SP2 may move to the outside of the chamber CH to receive the deposition mask MK and then enter the inside of the chamber CH from the outside, for example.

In the above case, the first support SP1 and the second support SP2 may be formed integrally. In such a case, the first support SP1 and the second support SP2 may include a movable shuttle. Here, the first support SP1 and the second support SP2 include a structure that fixes the deposition mask MK and the display substrate DS in a state where the display substrate DS is seated on the deposition mask MK, and may be capable of linearly moving the display substrate DS and the deposition mask MK simultaneously.

However, for the convenience of explanation, the following description will focus on a configuration in which the first support SP1 and the second support SP2 are distinct from each other and are arranged at different positions, and in which the first support SP1 and the second support SP2 are arranged inside the chamber CH.

The deposition mask MK may be placed inside the chamber CH so as to face the display substrate DS. A deposition material M may pass through the deposition mask MK and be deposited on the display substrate DS.

The deposition source SC may be disposed to face the deposition mask MK and may supply the deposition material M so that the deposition material M passes through the deposition mask MK and is deposited on the display substrate DS. At this time, the deposition source SC may evaporate or sublimate the deposition material M by applying heat to the deposition material M. The deposition source SC may be fixed inside the chamber CH, or may be disposed inside the chamber CH to be linearly movable in one direction.

The magnetic force portion MG may be disposed inside the chamber CH so as to face the display substrate DS and/or the deposition mask MK. In an embodiment, the magnetic force portion MG may apply magnetic force to the deposition mask MK to press the deposition mask MK toward the display substrate DS.

The vision portion VS may be disposed inside the chamber CH and may capture images of the positions of the display substrate DS and the deposition mask MK. The vision portion VS may include a camera for photographing the display substrate DS and the deposition mask MK. Based on the images captured by the vision portion VS, the positions of the display substrate DS and the deposition mask MK may be identified, and any deformation of the deposition mask MK may be detected. Additionally, based on the images, the position of the display substrate DS on the first support SP1 or the position of the deposition mask MK on the second support SP2 may be finely adjusted. However, the following description will focus primarily on the case in which the position of the deposition mask MK on the second support SP2 is finely adjusted to align the positions of the display substrate DS and the deposition mask MK.

The pressure controller PSC may be connected to the chamber CH and may control the internal pressure of the chamber CH. In an embodiment, the pressure controller PSC may control the pressure inside the chamber CH to be the same as or similar to atmospheric pressure, for example. Additionally, the pressure controller PSC may control the pressure inside the chamber CH to be the same as or similar to a vacuum state.

The pressure controller PSC may include a connection pipe 81 connected to the chamber CH and a pump 82 installed at the connection pipe 81. Depending on the operation of the pump 82, external air may flow in through the connection pipe 81, or gas inside the chamber CH may be guided to the outside through the connection pipe 81.

A method of manufacturing a display device (not shown) using the apparatus 1 for manufacturing a display device described above may be as follows: first, the display substrate DS may be prepared.

The pressure controller PSC may maintain the internal pressure of the chamber CH at the same as or similar to atmospheric pressure, and the gate valve GB may operate to open the open portion of the chamber CH.

Thereafter, the display substrate DS may be loaded from the outside of the chamber CH to the inside of the chamber CH. In an embodiment, the display substrate DS may be loaded into the chamber CH in various ways. In an embodiment, the display substrate DS may be loaded into the chamber CH from the outside via a robot arm or the like placed outside the chamber CH, for example. In another embodiment, when the first support SP1 is formed in the form of a shuttle, the first support SP1 may be transported from the inside of the chamber CH to the outside of the chamber CH, and then the display substrate DS may be seated on the first support SP1 using a separate robot arm or the like placed outside the chamber CH, and the first support SP1 may then be loaded into the chamber CH from the outside of the chamber CH.

The deposition mask MK may be placed inside the chamber CH as described above. In another embodiment, the deposition mask MK may also be loaded into the chamber CH from the outside of the chamber CH in the same or similar manner as the display substrate DS.

When the display substrate DS is loaded into the inside of the chamber CH, the display substrate DS may be seated on the first support SP1. At this time, the vision portion VS may capture images of the positions of the display substrate DS and the deposition mask MK. Based on the images captured by the vision portion VS, the positions of the display substrate DS and deposition mask MK may be identified. At this time, the apparatus 1 for manufacturing a display device is provided with a separate controller (not shown) to identify the positions of the display substrate DS and the deposition mask MK.

Once the positions of the display substrate DS and the deposition mask MK have been identified, the second support SP2 may finely adjust the position of the deposition mask MK.

Thereafter, the deposition source SC may operate to supply the deposition material M toward the deposition mask MK, and the deposition material M that has passed through the deposition mask MK may be deposited on the display substrate DS. In an embodiment, the deposition source SC may move in parallel with respect to the display substrate DS and the deposition mask MK, or the display substrate DS and the deposition mask MK may move in parallel with respect to the deposition source SC. In other words, the deposition source SC may move relative to the display substrate DS and the deposition mask MK. At this time, the pump 82 may maintain the internal pressure of the chamber CH at a state that is the same as or similar to a vacuum by drawing gas from the inside of the chamber CH and discharging it to the outside.

As described above, the deposition material M supplied from the deposition source SC may pass through the deposition mask MK and may be deposited on the display substrate DS, thereby forming at least one of multiple layers laminated in the display device to be described below, for example, an organic layer, an inorganic layer, and a metal layer.

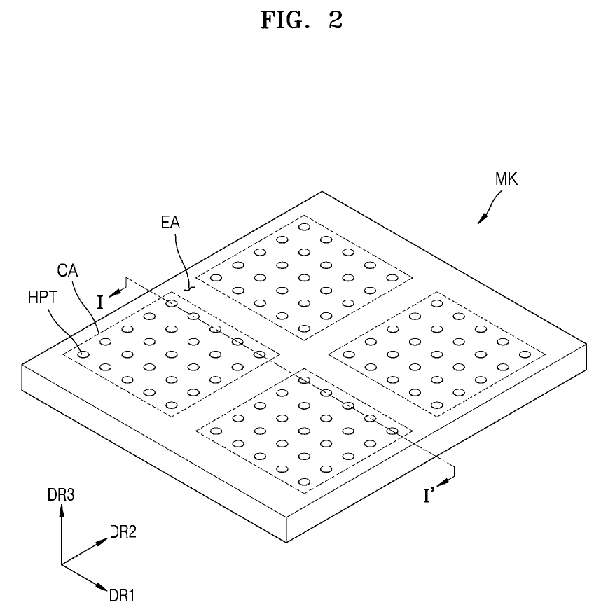

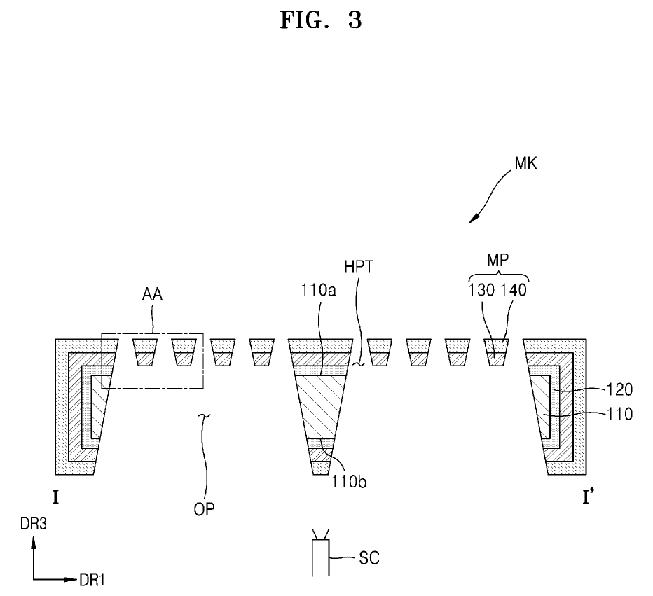

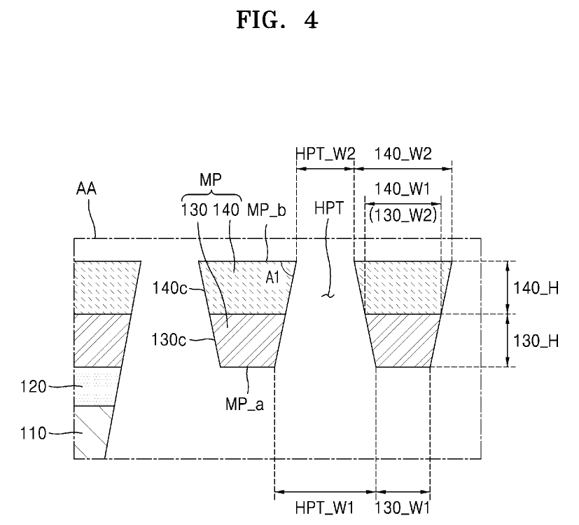

FIG. 2 is a schematic plan view of an embodiment of a deposition mask of the disclosure, FIG. 3 is a schematic cross-sectional view of the deposition mask taken along line I-I' of FIG. 2, and FIG. 4 is an enlarged view of area AA of FIG. 3.

A deposition mask MK in an embodiment of the disclosure may be a mask used for manufacturing an ultra-high-resolution display panel. In an embodiment, the deposition mask MK may be a mask used for manufacturing a display panel included in an extended reality device (“XR” device), such as a virtual reality (“VR”) device, an augmented reality (“AR”) device, or a mixed reality (“MR”) device, for example.

In an embodiment, the deposition mask MK may be used to perform a pixel deposition process on a silicon wafer rather than on a large-area substrate typically used in conventional display panels. In the case of a display panel included in an extended reality device, since the screen is disposed directly in front of the user's eyes, the panel may be of a relatively small size rather than a relatively large area. Additionally, because it is disposed close to the user's eyes, ultra-high resolution may be desired. In an embodiment, the desired resolution of a display panel included in an extended reality device may be about 1000 pixels per inch (PPI) or more, and preferably an ultra-high resolution of 2000 PPI or more may be desired, for example. A deposition mask MK in an embodiment may be a mask used for manufacturing such an ultra-high-resolution display panel.

Referring to FIG. 2, the deposition mask MK may have two first sides extending in a first direction DR1 and two second sides extending in a second direction DR2. The second direction DR2 may be a direction intersecting the first direction DR1. In an embodiment, the second direction DR2 may be perpendicular to the first direction DR1.

The deposition mask MK may be a thin plate having a relatively small thickness in a third direction DR3. The third direction DR3 may be a direction that intersects substantially perpendicularly with a plane defined by the first direction DR1 and the second direction DR2. The expression "in the plan view" as used herein may refer to a state as viewed along the third direction DR3.

The deposition mask MK may define a cell area CA and a peripheral area EA surrounding the cell area CA in the plan view. In an embodiment, a plurality of cell areas CA may be provided and spaced apart from one another with the peripheral area EA disposed between them. The plurality of cell areas CA may be arranged along the first direction DR1 and/or the second direction DR2. The cell areas CA may be arranged along either the first direction DR1 or the second direction DR2, or, as in the illustrated example, may be arranged along the first direction DR1 and the second direction DR2 to have a matrix arrangement. However, the cell areas CA are not limited to any particular embodiment.

The peripheral area EA surrounds each of the cell areas CA and may be an area that connects the cell areas CA. The deposition mask MK may be formed in the shape of a single integral plate in which a plurality of cell areas CA are connected, but the disclosure is not limited thereto.

In each cell area CA, a plurality of hole patterns HPT penetrating the deposition mask MK along the third direction DR3, i.e., in the thickness direction, may be defined. The deposition material supplied from the deposition source SC may pass through the deposition mask MK via the hole pattern HPT of the deposition mask MK.

In one cell area CA, the plurality of hole patterns HPT may be arranged spaced apart from each other. In an embodiment, FIG. 2 illustrates a plurality of hole patterns HPT arranged along the first direction DR1 and the second direction DR2, for example. However, the disclosure is not limited to this, such that the plurality of hole patterns HPT may be defined to correspond to a pattern shape to be deposited on a display substrate DS (refer to FIG. 1).

Referring to FIGS. 3 and 4, the deposition mask MK may include a mask substrate 110, an oxide layer 120, and a mask pattern MP. In an embodiment, the deposition mask MK may be a mask in which the mask pattern MP is directly disposed (e.g., mounted) on the mask substrate 110.

The mask substrate 110 may include a silicon wafer. Since a silicon wafer allows for more precise and fine processing compared to a large-area substrate by utilizing technologies developed in semiconductor processes, it may be adopted as a substrate for an ultra-high-resolution display panel. The deposition mask MK in an embodiment may also use a silicon wafer to form pixels on a silicon wafer of such an ultra-high-resolution display panel.

The shape of the mask substrate 110 may correspond to the shape of a silicon wafer of an ultra-high-resolution display panel. In an embodiment, the mask substrate 110 may have the same size as or the same shape as that of the silicon wafer of the ultra-high-resolution display panel, for example.

However, the disclosure is not limited to this. In another embodiment, the mask substrate 110 may include a large-area substrate. In an embodiment, the mask substrate 110 may include a material such as glass, quartz, or polymer resin, for example.

The mask substrate 110 may define an opening OP that penetrates from one surface 110a to a remaining (the other) surface 110b. The opening OP may provide a passage through which the deposition material may move toward the mask pattern MP. In areas other than the area in which the opening OP is disposed, the mask substrate 110 may block the movement of the deposition material. The mask substrate 110 may serve to support the mask pattern MP.

The opening OP may be disposed to overlap with the mask pattern MP along the third direction DR3, as will be described below. The opening OP may be formed by forming the mask pattern MP on one surface 110a of the mask substrate 110 and then removing a portion of the mask substrate 110 so as to overlap with the formed mask pattern MP.

The inner side surface of the opening OP may be an inclined surface. When the opening OP is formed by wet etching, the inner side surface of the opening OP may become inclined due to the isotropic nature of the etching solution.

The oxide layer 120 may be disposed on the mask substrate 110. The oxide layer 120 may be disposed between the mask pattern MP and the mask substrate 110. The oxide layer 120 may be disposed on an area of the mask substrate 110 in which the opening OP is not formed. In an embodiment, the oxide layer 120 may be formed as an insulating film including or consisting of a material such as silicon oxide, for example.

In an embodiment, the oxide layer 120 may cover the entirety of the surface of the mask substrate 110. In an embodiment, when the mask substrate 110 has a plate shape, the oxide layer 120 may be disposed to cover the upper surface, lower surface, and side surfaces of the mask substrate 110, for example. In another embodiment, the oxide layer 120 may be disposed only on one surface 110a of the outer surface of the mask substrate 110 that is next (adjacent) to the mask pattern MP. The oxide layer 120 may serve to prevent deformation of the mask pattern MP during the manufacturing process of the deposition mask MK.

The mask pattern MP may be disposed on one surface 110a of the mask substrate 110. The mask pattern MP may include a plurality of patterns spaced apart from each other in the first direction DR1 or the second direction DR2 in a cross-sectional view. Although the plurality of patterns are spaced apart in cross-section, they may form a single connected mask pattern MP in a planar view. Hereinafter, the term "mask pattern MP" may refer to the entirety of the group of a plurality of patterns disposed on the mask substrate 110 as a single configuration, or it may refer to each of the individual patterns. That is, the term "mask pattern MP" may be used interchangeably to refer to the collection of multiple patterns as a single configuration or to refer to each individual pattern.

The mask pattern MP may include a first insulating layer 130 and a second insulating layer 140. The first insulating layer 130 and the second insulating layer 140 may be sequentially stacked on the oxide layer 120. In an embodiment, when the oxide layer 120 is formed to cover the entirety of the surface of the mask substrate 110, the first insulating layer 130 may be formed to cover the entirety of the surface of the oxide layer 120, and the second insulating layer 140 may be formed to cover the entirety of the surface of the first insulating layer 130. In another embodiment, the first insulating layer 130 and the second insulating layer 140 may be formed only on one surface 110a of the mask substrate 110 corresponding to the location of the mask pattern MP.

The first insulating layer 130 or the second insulating layer 140 may include or consist of a material that may be patterned through a semiconductor process. In an embodiment, the first insulating layer 130 or the second insulating layer 140 may be formed as an insulating film including or consisting of a material such as silicon oxide or silicon nitride (SiNx), for example. The first insulating layer 130 and the second insulating layer 140 may include the same material, but the embodiment is not limited to this.

In an embodiment, the first insulating layer 130 or the second insulating layer 140 may be a low-stress silicon nitride film formed by low-pressure chemical vapor deposition (“LPCVD”), plasma-enhanced chemical vapor deposition (“PECVD”), or the like.

When the first insulating layer 130 and the second insulating layer 140 are formed as silicon nitride films, the first insulating layer 130 and the second insulating layer 140 may have different composition ratios. In an embodiment, the first insulating layer 130 may have an atomic ratio of nitrogen (N) to silicon (Si) of 0.85 or more and less than 0.95, and the second insulating layer 140 may have an atomic ratio of nitrogen (N) to silicon (Si) of 0.95 or more, for example.

In an embodiment, the first insulating layer 130 and the second insulating layer 140 may have different etch selectivities with respect to the same mask material. In an embodiment, in an etching process using a photoresist as a mask, the etch selectivity with respect to the photoresist may be higher for the first insulating layer 130 than for the second insulating layer 140, for example. In an embodiment, the etch selectivity of the second insulating layer 140 with respect to the photoresist (second insulating layer 140:photoresist) may be about 1:1.01 to 1:1.1, and the etch selectivity of the first insulating layer 130 with respect to the photoresist (first insulating layer 130:photoresist) may be 1:0.7 to 1:0.8. That is, the first insulating layer 130 may have a higher etch rate than the photoresist, and the second insulating layer 140 may have an etch rate similar to or relatively lower than that of the photoresist.

In an embodiment, the etch rate of the first insulating layer 130 may be greater than the etch rate of the second insulating layer 140. In an embodiment, in the same etching process (e.g., a dry etching process using a fluorine-based gas), the etch rate of the first insulating layer 130 may be about 700 nanometers per minute (nm/min) to 1000 nm/min, preferably about 800 nm/min to 900 nm/min, and the etch rate of the second insulating layer 140 may be about 400 nm/min to 700 nm/min, preferably about 500 nm/min to 600 nm/min, for example. Due to the difference in etch rates between the first insulating layer 130 and the second insulating layer 140, the first insulating layer 130 may be etched relatively more than the second insulating layer 140.

In an embodiment, the first insulating layer 130 and the second insulating layer 140 may be formed by different deposition processes. In an embodiment, the second insulating layer 140 may be formed by a deposition process at a slower rate or a deposition process at a higher temperature than that used for the first insulating layer 130, for example. In an embodiment, the second insulating layer 140 may have a higher film density or a denser film characteristic than the first insulating layer 130. In an embodiment, the film density of the second insulating layer 140 may be about 2.95 grams per cubic centimeter (g/cm³) to 3.65 g/cm³, preferably about 3.25 g/cm³ to 3.45 g/cm³, and the film density of the first insulating layer 130 may be about 2.25 g/cm³ to 2.85 g/cm³, preferably about 2.45 g/cm³ to 2.65 g/cm³, for example.

In an embodiment, the second insulating layer 140 may have a higher stress than the first insulating layer 130. In an embodiment, the stress of the first insulating layer 130 may include or consist of a range of about170 megapascals (MPa) to 190 MPa, and the stress of the second insulating layer 140 may include or consist of a range of about 190 MPa to 210 MPa, for example.

In an embodiment, the deposition temperature of the first insulating layer 130 may include or consist of a range of about 100 degrees Celsius (°C) to 400° C, and the deposition temperature of the second insulating layer 140 may include or consist of a range of about 500° C to 900° C

In an embodiment, the first insulating layer 130 may be deposited by PECVD, and the second insulating layer 140 may be deposited by LPCVD, but the disclosure is not limited thereto.

The deposition mask MK may include a plurality of hole patterns HPT that penetrate through the first insulating layer 130 and the second insulating layer 140 along the third direction DR3. A plurality of hole patterns HPT may be arranged between neighboring (adjacent) mask patterns MP and may be spaced apart from one another to form a selectable arrangement. In FIG. 2, each hole pattern HPT is illustrated as being circular in shape when viewed in a planar view in an embodiment, but it is not limited to this, and the shape of the hole pattern HPT may be modified into various shapes such as squares, rectangles, hexagons, or the like, depending on the purpose and application.

In an embodiment, all of the plurality of hole patterns HPT may overlap the opening OP of the mask substrate 110. Accordingly, the deposition material of the deposition source SC that passes through the opening OP may reach the plurality of hole patterns HPT.

On the plane, the areas of the plurality of hole patterns HPT penetrating each of the first insulating layer 130 and the second insulating layer 140 may be different in each layer. In an embodiment, along the third direction DR3, the areas of the plurality of hole patterns HPT in the plan view may become narrower from the first insulating layer 130 toward the second insulating layer 140, for example.

In an embodiment, the cross-section of each hole pattern HPT may have a trapezoidal shape. In an embodiment, an upper width HPT_W2 of each hole pattern HPT may be narrower than a lower width HPT_W1, for example. In this specification, the width of a hole pattern HPT may be defined as the length in the first direction DR1. Along the third direction DR3, the width of each of the plurality of hole patterns HPT may gradually decrease as the distance from the deposition source SC increases.

The cross-section of each mask pattern MP may have a reverse taper shape in which the width increases from the rear surface MP_a toward the top surface MP_b. In this specification, the width of the mask pattern MP may be defined as the length in the first direction DR1. Here, the rear surface MP_a of the mask pattern MP refers to a surface facing the deposition source SC, and the top surface MP_b of the mask pattern MP refers to a surface facing the substrate to be deposited on the display substrate DS (refer to FIG. 1), for example.

In an embodiment, the rear surface MP_a of the mask pattern MP may be the rear surface of the first insulating layer 130, and the top surface MP_b of the mask pattern MP may be the top surface of the second insulating layer 140. The top surface of the first insulating layer 130 and the rear surface of the second insulating layer 140 may contact each other. In the cross-section of the mask pattern MP, a width 130_W1 of the rear surface of the first insulating layer 130 may be less than a width 130_W2 of the top surface of the first insulating layer 130, and a width 140_W1 of the rear surface of the second insulating layer 140 may be less than a width 140_W2 of the top surface of the second insulating layer 140.

In an embodiment, side surfaces 130c of the first insulating layer 130 and side surfaces 140c of the second insulating layer 140, which define the plurality of hole patterns HPT, may be inclined surfaces having the same angle or angles within a selectable range. In an embodiment, the side surface 130c of the first insulating layer 130 and the side surface 140c of the second insulating layer 140 may form a single continuous inclined surface, for example. In an embodiment, an angle A1 formed between the side surface 140c of the second insulating layer 140 and the top surface MP_b of the mask pattern MP may be designed to be about 60 degrees to 89 degrees, for example.

A height 130_H of the first insulating layer 130 and a height 140_H of the second insulating layer 140 may be determined by taking into consideration the durability, production speed, or the like of the deposition mask MK. Here, the height 130_H of the first insulating layer 130 and the height 140_H of the second insulating layer 140 respectively refer to the lengths of the first insulating layer 130 and the second insulating layer 140 extending in the third direction DR3.

In an embodiment, the height 130_H of the first insulating layer 130 may be greater than the height 140_H of the second insulating layer 140. When the first insulating layer 130, which has a relatively fast deposition rate and higher etch rate, is formed thicker than the second insulating layer 140, the production speed of the deposition mask MK may be increased.

In an embodiment, the height 130_H of the first insulating layer 130 may be less than or equal to the height 140_H of the second insulating layer 140. As the height 140_H of the second insulating layer 140 increases relative to the overall height of the mask pattern MP, the durability of the deposition mask MK may be increased.

In an embodiment, the thickness of the mask pattern MP may be 0.1 micrometers (μm) or more and 5 μm or less. Here, the thickness of the mask pattern MP may be the sum of the height 130_H of the first insulating layer 130 and the height 140_H of the second insulating layer 140. In case that the thickness of the mask pattern MP is less than 0.1 μm, the durability of the deposition mask MK may be degraded. In case that the thickness of the mask pattern MP is greater than 5 μm, the overall thickness of the deposition mask MK increases, which may reduce deposition precision during the deposition process.

The mask pattern MP in an embodiment, having a reverse taper shape, may reduce defects such as shadow regions in which a deposition material is insufficiently supplied in a portion defined as a deposition area on the display substrate DS (refer to FIG. 1). Accordingly, the deposition mask MK in an embodiment of the disclosure may reduce shadow defects, suppress accumulation of deposition material on the mask MK, and improve the deposition efficiency of the deposition material. In addition, the deposition mask MK in an embodiment of the disclosure is suitable for manufacturing a high-resolution organic light-emitting display device, and may enhance pixel position accuracy (“PPA”), thereby improving reliability.

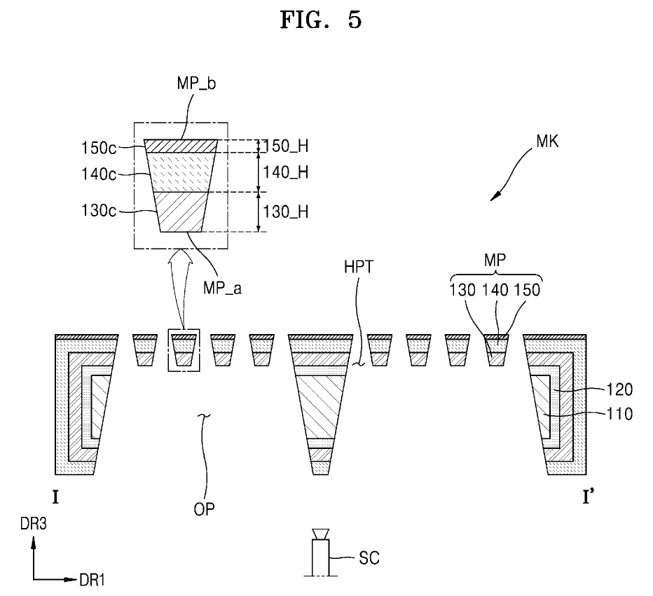

FIG. 5 is a schematic cross-sectional view of an embodiment of a deposition mask of the disclosure.

The embodiment of FIG. 5 is different from the embodiments of FIGS. 3 and 4 in that a first carbon layer 150 is additionally disposed on the second insulating layer 140. Hereinafter, only the differences of the embodiment of FIG. 5 compared to the embodiments of FIGS. 3 and 4 will be described, and features not described with respect to FIG. 5 will be understood from the descriptions of the embodiments of FIGS. 3 and 4.

Referring to FIG. 5, a mask pattern MP of a deposition mask MK in an embodiment of the disclosure may have a structure in which a first insulating layer 130, a second insulating layer 140, and a first carbon layer 150 are stacked. Additionally, the deposition mask MK may include a plurality of hole patterns HPT that penetrate through the first insulating layer 130, the second insulating layer 140, and the first carbon layer 150 along the third direction DR3.

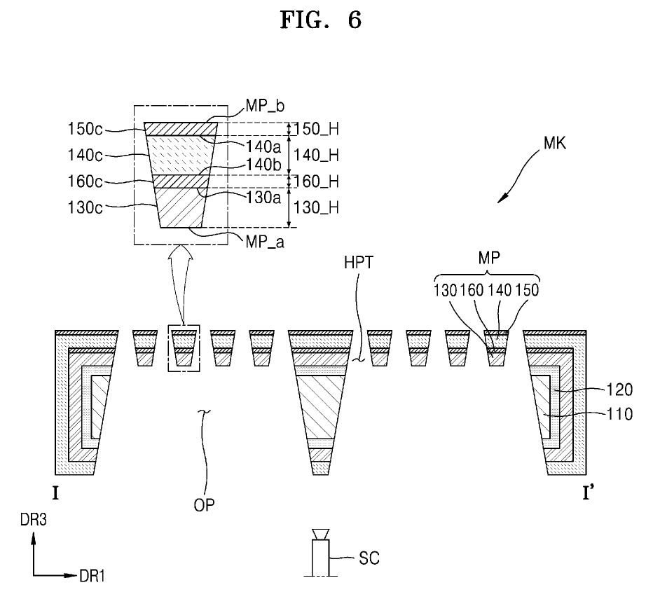

The first carbon layer 150 may be disposed on the top surface 140a (refer to FIG. 6) of the second insulating layer 140. The first carbon layer 150 may contact the top surface 140a of the second insulating layer 140. The first carbon layer 150 may include or consist of a material having good wear resistance. In an embodiment, the first carbon layer 150 may include amorphous carbon, for example. The first carbon layer 150 may cover the top surface 140a of the second insulating layer 140 and serve to protect the second insulating layer 140. By arranging the first carbon layer 150 on the surface of the deposition mask MK that faces the display substrate DS, the deposition mask MK in an embodiment of the disclosure may reduce the defect rate during the manufacturing process and improve durability.

On the plane, the areas of the plurality of hole patterns HPT penetrating each of the first insulating layer 130, the second insulating layer 140 and the first carbon layer 150 may be different in each layer. In an embodiment, along the third direction DR3, the areas of the plurality of hole patterns HPT in the plan view may become narrower from the first insulating layer 130 toward the first carbon layer 150, for example.

The cross-section of each mask pattern MP may have a reverse taper shape in which the width increases from the rear surface MP_a toward the top surface MP_b. Here, the rear surface MP_a of the mask pattern MP corresponds to the rear surface of the first insulating layer 130, and the top surface MP_b of the mask pattern MP corresponds to the top surface of the first carbon layer 150.

In the cross-section of the mask pattern MP, the width of the top surface of the first carbon layer 150 may be greater than the width of the rear surface of the first carbon layer 150. The width of the rear surface of the first carbon layer 150 may be greater than or equal to the width of the top surface of the second insulating layer 140.

In an embodiment, the side surfaces 130c of the first insulating layer 130, the side surfaces 140c of the second insulating layer 140, and the side surfaces 150c of the first carbon layer 150, which define the plurality of hole patterns HPT, may be inclined surfaces having the same angle or angles within a selectable range. In an embodiment, the side surface 130c of the first insulating layer 130, the side surface 140c of the second insulating layer 140, and the side surface 150c of the first carbon layer 150 may form a single continuous inclined surface, for example.

In an embodiment, the height 150_H of the first carbon layer 150 may be less than the height 130_H of the first insulating layer 130 or the height 140_H of the second insulating layer 140. In an embodiment, the height 150_H of the first carbon layer 150 may be less than or equal to half of the height 130_H of the first insulating layer 130 or the height 140_H of the second insulating layer 140, for example.

FIG. 6 is a schematic cross-sectional view of an embodiment of a deposition mask of the disclosure.

The embodiment of FIG. 6 is different from the embodiment of FIG. 5 in that a second carbon layer 160 is additionally disposed between the first insulating layer 130 and the second insulating layer 140. Hereinafter, only the differences of the embodiment of FIG. 6 compared to the embodiment of FIG. 5 will be described, and features not described with respect to FIG. 6 will be understood from the descriptions of the embodiments of FIGS. 3, 4, and 5.

Referring to FIG. 6, a mask pattern MP of a deposition mask MK in an embodiment of the disclosure may have a structure in which a first insulating layer 130, a second carbon layer 160, a second insulating layer 140, and a first carbon layer 150 are stacked. Additionally, the deposition mask MK may include a plurality of hole patterns HPT that penetrate through the first insulating layer 130, the second carbon layer 160, the second insulating layer 140, and the first carbon layer 150 along the third direction DR3.

The second carbon layer 160 may be disposed between the first insulating layer 130 and the second insulating layer 140. The rear surface of the second carbon layer 160 may contact the top surface 130a of the first insulating layer 130, and the top surface of the second carbon layer 160 may contact the rear surface 140b of the second insulating layer 140.

The second carbon layer 160 may include or consist of a material having good wear resistance. In an embodiment, the second carbon layer 160 may include amorphous carbon, for example. The second carbon layer 160 may support the first insulating layer 130 and the second insulating layer 140 and may serve to improve the durability of the mask pattern MP. By arranging the first carbon layer 150 on the surface facing the display substrate DS and the second carbon layer 160 between the first insulating layer 130 and the second insulating layer 140, the deposition mask MK in an embodiment of the disclosure may reduce the defect rate due to damage to the mask pattern MP during the manufacturing process and may improve the durability of the deposition mask MK.

The areas of the plurality of hole patterns HPT penetrating through each of the first insulating layer 130, the second carbon layer 160, the second insulating layer 140, and the first carbon layer 150 in a plan view may be different in each layer. In an embodiment, along the third direction DR3, the areas of the plurality of hole patterns HPT in the plan view may become narrower from the first insulating layer 130 toward the first carbon layer 150, for example.

The cross-section of each mask pattern MP may have a reverse taper shape in which the width increases from the rear surface MP_a toward the top surface MP_b. Here, the rear surface MP_a of the mask pattern MP corresponds to the rear surface of the first insulating layer 130, and the top surface MP_b of the mask pattern MP corresponds to the top surface of the first carbon layer 150.

In the cross-section of the mask pattern MP, the width of the top surface of the second carbon layer 160 may be greater than the width of the rear surface of the second carbon layer 160. The width of the top surface of the second carbon layer 160 may be greater than or equal to the width of the rear surface 140b of the second insulating layer 140, and the width of the rear surface of the second carbon layer 160 may be greater than or equal to the width of the top surface 130a of the first insulating layer 130.

In an embodiment, the side surfaces 130c of the first insulating layer 130, the side surfaces 160c of the second carbon layer 160, the side surfaces 140c of the second insulating layer 140, and the side surfaces 150c of the first carbon layer 150, which define the plurality of hole patterns HPT, may be inclined surfaces having the same angle or angles within a selectable range. In an embodiment, the side surface 130c of the first insulating layer 130, the side surface 160c of the second carbon layer 160, the side surface 140c of the second insulating layer 140, and the side surface 150c of the first carbon layer 150 may form a single continuous inclined surface, for example.

In an embodiment, the height 160_H of the second carbon layer 160 may be less than the height 130_H of the first insulating layer 130 or the height 140_H of the second insulating layer 140. In an embodiment, the height 160_H of the second carbon layer 160 may be less than or equal to half of the height 130_H of the first insulating layer 130 or the height 140_H of the second insulating layer 140, for example. The height 160_H of the second carbon layer 160 may be equal to the height 150_H of the first carbon layer 150, but the embodiment is not limited to this.

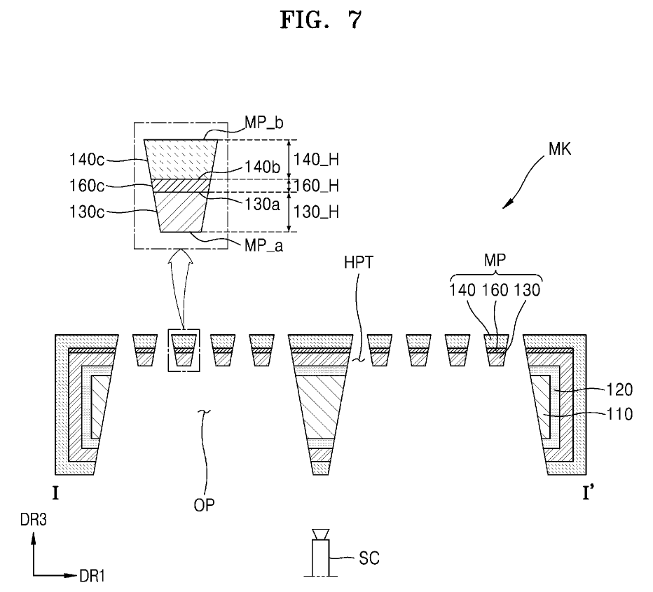

FIG. 7 is a schematic cross-sectional view of an embodiment of a deposition mask of the disclosure.

The embodiment of FIG. 7 is different from the embodiment of FIG. 6 in that a first carbon layer 150 is not disposed on the second insulating layer 140. Hereinafter, only the differences between the embodiment of FIG. 7 and the embodiment of FIG. 6 will be described. Accordingly, features not described with respect to FIG. 7 will be understood from the description of the embodiment of FIG. 6.

Referring to FIG. 7, a mask pattern MP of a deposition mask MK in an embodiment of the disclosure may have a structure in which a first insulating layer 130, a second carbon layer 160, and a second insulating layer 140 are stacked. Additionally, the deposition mask MK may include a plurality of hole patterns HPT that penetrate through the first insulating layer 130, the second carbon layer 160, and the second insulating layer 140 along the third direction DR3.

The second carbon layer 160 may be placed between the first insulating layer 130 and the second insulating layer 140 and may serve to prevent damage to the first insulating layer 130 and the second insulating layer 140 during the manufacture of the deposition mask MK. The side surface 130c of the first insulating layer 130, the side surface 160c of the second carbon layer 160, and the side surface 140c of the second insulating layer 140 may be connected to define a hole pattern HPT.

The rear surface MP_a of the mask pattern MP corresponds to the rear surface of the first insulating layer 130, and the top surface MP_b of the mask pattern MP corresponds to the top surface of the second insulating layer 140. The cross-section of each mask pattern MP may have a reverse taper shape in which the width increases from the rear surface MP_a toward the top surface MP_b.

In the cross-section of the mask pattern MP, the width of the top surface of the second carbon layer 160 may be greater than the width of the rear surface of the second carbon layer 160. The width of the top surface of the second carbon layer 160 may be greater than or equal to the width of the rear surface 140b of the second insulating layer 140, and the width of the rear surface of the second carbon layer 160 may be greater than or equal to the width of the top surface 130a of the first insulating layer 130.

The height 160_H of the second carbon layer 160 may be less than the height 130_H of the first insulating layer 130 or the height 140_H of the second insulating layer 140. In an embodiment, the height 160_H of the second carbon layer 160 may be less than or equal to half of the height 130_H of the first insulating layer 130 or the height 140_H of the second insulating layer 140, for example.

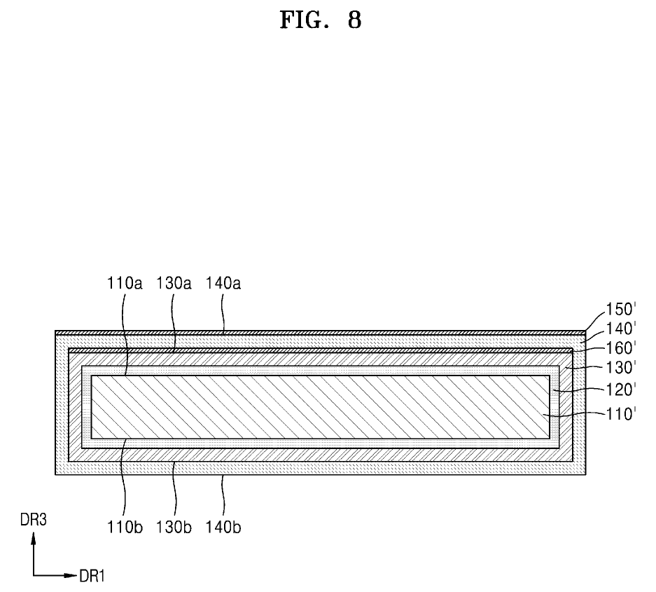

Hereinafter, a method of manufacturing a deposition mask in an embodiment of the disclosure will be described in detail with reference to FIGS. 8 - 13. In FIGS. 8 - 13, a method of manufacturing a deposition mask in the embodiment of FIG. 7 is described, but it is to be understood that the method of manufacturing a deposition mask in an embodiment of the disclosure, as will be described with reference to FIGS. 8 - 13, may be modified in accordance with the methods of manufacturing the deposition masks illustrated in the embodiment of FIGS. 3 - 6.

First, as illustrated in FIG. 8, a preliminary oxidation layer 120', a first preliminary insulating layer 130', a second preliminary carbon layer 160', a second preliminary insulating layer 140', and a first preliminary carbon layer 150' are formed on a preliminary mask substrate 110'. In the description, the first preliminary carbon layer 150' and the second preliminary carbon layer 160' may be collectively referred to as a preliminary carbon layer for convenience.

The preliminary mask substrate 110' has a plate shape including a top surface 110a and a rear surface 110b, and may correspond to a workpiece in a state prior to formation of an opening OP (refer to FIG. 7). The preliminary mask substrate 110' may use a substrate including or consisting of silicon material, and In an embodiment, a silicon wafer may be used.

The preliminary oxidation layer 120' may be stacked on a surface of the preliminary mask substrate 110'. The preliminary oxidation layer 120' may be stacked on both the top surface 110a and the rear surface 110b of the preliminary mask substrate 110', but is not limited to this and may be stacked only on the top surface 110a of the preliminary mask substrate 110'. In an embodiment, the preliminary oxidation layer 120' may be formed as a thin film including silicon oxide, for example.

The first preliminary insulating layer 130' may be stacked on the surface of the preliminary oxidation layer 120'. In an embodiment, the first preliminary insulating layer 130' may be deposited by LPCVD or PECVD.

The first preliminary insulating layer 130' may be formed as a thin film including silicon oxide or silicon nitride. In an embodiment, the first preliminary insulating layer 130' may be formed as a low-stress silicon nitride film, for example. The first preliminary insulating layer 130' may include a top surface 130a and a rear surface 130b corresponding to the top surface 110a and the rear surface 110b of the preliminary mask substrate 110', respectively.

The second preliminary carbon layer 160' may be stacked on one surface (top surface 130a) of the first preliminary insulating layer 130'. The second preliminary carbon layer 160' may include amorphous carbon. The thickness of the second preliminary carbon layer 160' may be less than the thickness of the first preliminary insulating layer 130'.

The second preliminary insulating layer 140' may be stacked on the surface of the second preliminary carbon layer 160' and on the surface of the first preliminary insulating layer 130'. The second preliminary insulating layer 140' may include a top surface 140a and a rear surface 140b corresponding to the top surface 110a and the rear surface 110b of the preliminary mask substrate 110', respectively.

The second preliminary insulating layer 140' may be formed as a thin film including silicon oxide or silicon nitride. In an embodiment, the second preliminary insulating layer 140' may include the same material as that of the first preliminary insulating layer 130'. In an embodiment, the second preliminary insulating layer 140' may include or consist of a low-stress silicon nitride film, but is not limited thereto, for example.

In an embodiment, the second preliminary insulating layer 140' may be deposited by a low pressure chemical vapor deposition (“LPCVD”) method or a PECVD method. The second preliminary insulating layer 140' may be formed through a deposition process in which at least one deposition condition including the deposition temperature, deposition pressure, deposition speed, and deposition method is different from that used for the deposition process for forming the first preliminary insulating layer 130'.

In an embodiment, the deposition process for forming the second preliminary insulating layer 140' may have a slower deposition rate than the deposition process for forming the first preliminary insulating layer 130'. The deposited second preliminary insulating layer 140' may have a higher film density due to its relatively slower deposition speed, whereas the deposited first preliminary insulating layer 130' may have a lower film density due to its relatively faster deposition speed.

In an embodiment, the deposition temperature of the second preliminary insulating layer 140' may be higher than the deposition temperature of the first preliminary insulating layer 130'. In an embodiment, the deposition temperature of the first preliminary insulating layer 130' may be about 100° C to 400° C, and the deposition temperature of the second preliminary insulating layer 140' may be about 500° C to 900° C The second preliminary insulating layer 140' may exhibit denser film characteristics as the deposition temperature is higher than that of the first preliminary insulating layer 130', for example.

The first preliminary carbon layer 150' may be stacked on one surface (top surface 140a) of the second preliminary insulating layer 140'. The first preliminary carbon layer 150' may include amorphous carbon. The thickness of the first preliminary carbon layer 150' may be formed to correspond to the thickness of the second preliminary carbon layer 160'. The thickness of the first preliminary carbon layer 150' may be less than the thickness of the first preliminary insulating layer 130' or the second preliminary insulating layer 140'.

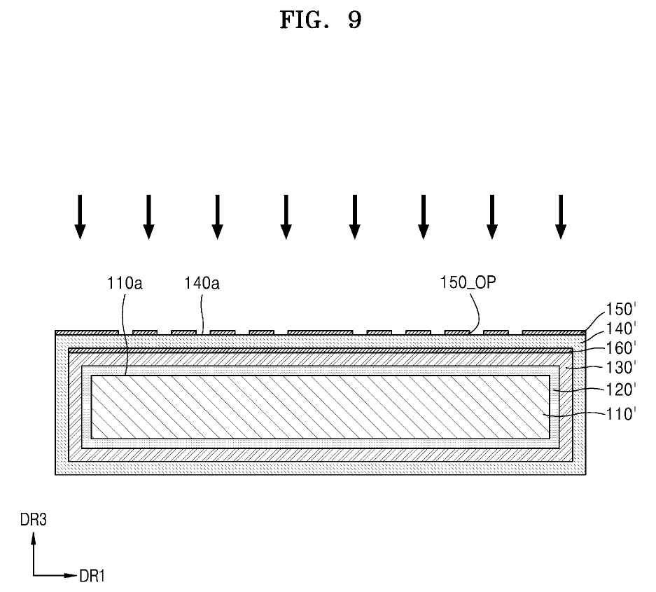

Next, the first preliminary carbon layer 150' is patterned as shown in FIG. 9. In an embodiment, the first preliminary carbon layer 150' may be patterned through a dry etching process using plasma, for example. However, the disclosure is not limited to this, and various known techniques may be applied to the patterning of the first preliminary carbon layer 150'.

A first opening 150_OP defined through patterning of the first preliminary carbon layer 150' may be formed corresponding to the location of the hole pattern HPT of the mask pattern MP. The top surface 140a of the second preliminary insulating layer 140' may be exposed through the first opening 150_OP penetrating the first preliminary carbon layer 150'.

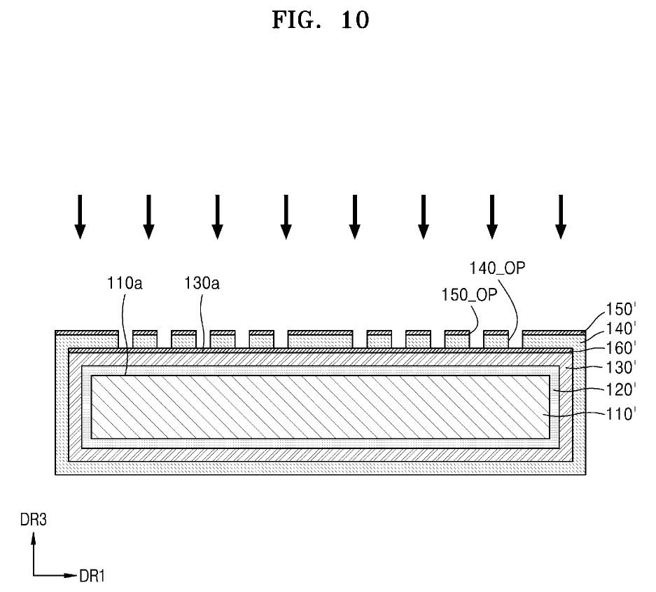

Next, as shown in FIG. 10, the second preliminary insulating layer 140' is patterned. The second preliminary insulating layer 140' may be patterned using the first preliminary carbon layer 150' as a mask. In an embodiment, the second preliminary insulating layer 140' may be patterned through a dry etching process such as reactive-ion etching (“RIE”), but is not limited to this, for example.

A second opening 140_OP formed through patterning of the second preliminary insulating layer 140' may be formed based on the position and size of the first opening 150_OP of the first preliminary carbon layer 150'. The top surface of the second preliminary carbon layer 160' may be exposed through the second opening 140_OP penetrating the second preliminary insulating layer 140'. After the patterning of the second preliminary insulating layer 140' is completed, the first preliminary carbon layer 150' may be removed through an etching process or the like.

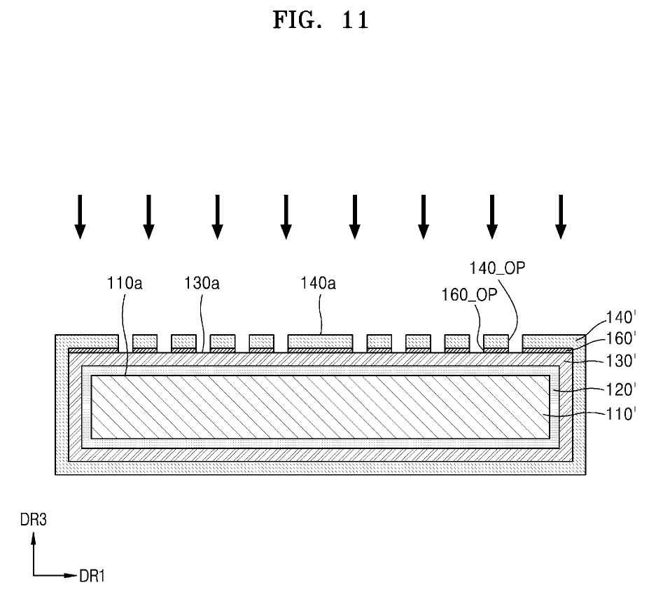

Next, as shown in FIG. 11, the second preliminary carbon layer 160' is patterned. In an embodiment, the second preliminary carbon layer 160' may be patterned through a dry etching process using plasma, but is not limited to this, for example.

A third opening 160_OP defined through patterning of the second preliminary carbon layer 160' may be formed based on the position and size of the second opening 140_OP of the second preliminary insulating layer 140'. The top surface 130a of the first preliminary insulating layer 130' may be exposed through the third opening 160_OP penetrating the second preliminary carbon layer 160'.

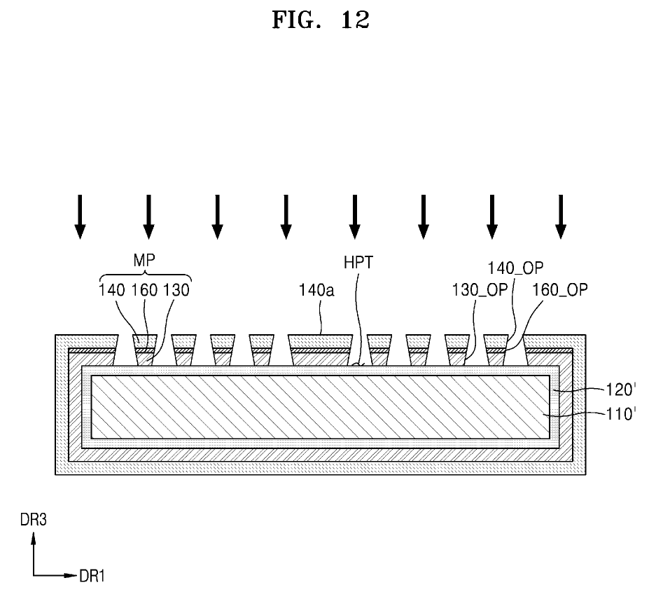

Next, as shown in FIG. 12, the first preliminary insulating layer 130' is patterned. In an embodiment, the first preliminary insulating layer 130' may be patterned through a dry etching process such as RIE, for example.

A fourth opening 130_OP defined through patterning of the first preliminary insulating layer 130' may be formed based on the position and size of the third opening 160_OP of the second preliminary carbon layer 160'. The top surface of the preliminary oxidation layer 120’ may be exposed through the fourth opening 130_OP penetrating the first preliminary insulating layer 130'.

In an embodiment, during patterning of the first preliminary insulating layer 130', a portion of the second preliminary insulating layer 140' may also be removed. In an embodiment, in the etching process for patterning the first preliminary insulating layer 130', as the first preliminary insulating layer 130' has a higher etch rate than the second preliminary insulating layer 140', the first preliminary insulating layer 130' may be etched at a faster rate than the second preliminary insulating layer 140' and the second preliminary insulating layer 140' may be etched more slowly, for example. After the patterning of the first preliminary insulating layer 130' is completed, the area of the remaining first insulating layer 130 may be smaller than the area of the second insulating layer 140.

The cross-section of the mask pattern MP may have a reverse taper shape, where the width increases from the rear surface toward the top surface, through the patterning of the first insulating layer 130, the second carbon layer 160, and the second insulating layer 140. In addition, the cross-sectional shape of the hole pattern HPT formed through the first insulating layer 130, the second carbon layer 160, and the second insulating layer 140 may have a trapezoidal shape (e.g., a positive taper shape) in which the upper width is narrower than the lower width.

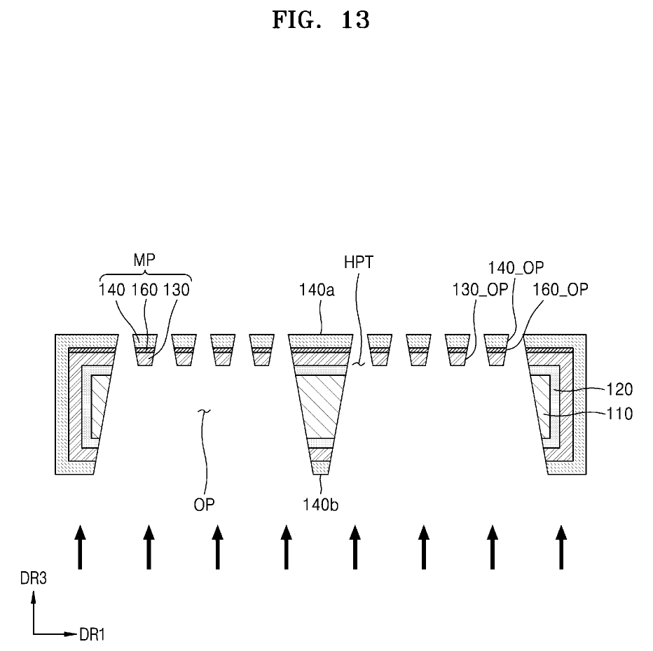

Next, as illustrated in FIG. 13 along with FIG. 12, an opening OP is formed by etching a portion of the rear surface 140b of the second preliminary insulating layer 140' in a direction from the rear surface 140b toward the top surface 140a, such that the opening OP is connected to the hole pattern HPT. The opening OP may be connected to the hole pattern HPT by removing, from the rear surface 140b of the second preliminary insulating layer 140′, portions of the second preliminary insulating layer 140’, portions of the first preliminary insulating layer 130’, portions of the preliminary oxidation layer 120', portions of the preliminary mask substrate 110', and a portion of the preliminary oxidation layer 120' disposed between the mask pattern MP and the preliminary mask substrate 110'.

Backside etching for forming the opening OP may employ a wet etching process, but is not limited to this. In an embodiment, the preliminary oxidation layer 120' between the preliminary mask substrate 110' and the mask pattern MP may serve as a stopper during the etching process. The opening OP may overlap with all of the plurality of hole patterns HPT and may be connected to the plurality of hole patterns HPT.

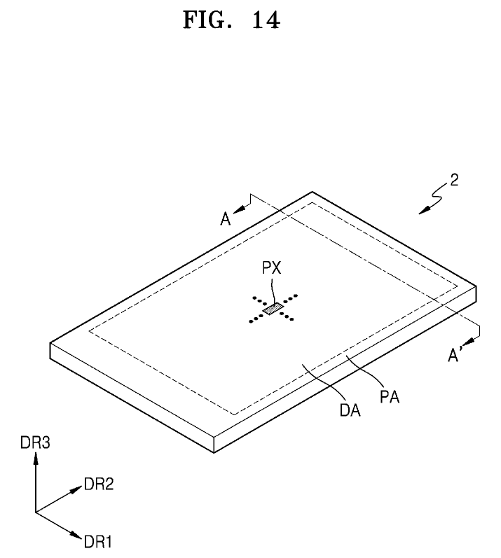

FIG. 14 is a schematic perspective view of an embodiment of a display device of the disclosure.

Referring to FIG. 14, a display device 2 includes a display area DA and a peripheral area PA surrounding the display area DA. The display area DA is a portion for displaying an image, and a plurality of pixels PX may be arranged in the display area DA. The display area DA may have various shapes, such as circular, elliptical, polygonal, or predetermined geometric shapes.

Each pixel PX of the display device 2 is a region that may emit light of a selected color, and the display device 2 may provide an image using the light emitted from the pixels PX. In an embodiment, each pixel PX may emit red, green, blue, or white light, for example. Each pixel PX corresponds to a sub-pixel and may include a display element and a pixel circuit connected thereto. The display element may include an organic light-emitting diode or a quantum dot organic light-emitting diode. The plurality of pixels PX may be arranged in a matrix form along a first direction DR1 and a second direction DR2.

The peripheral area PA may surround an entirety of the display area DA. The peripheral area PA may be a type of non-display area where no pixel is disposed, and drivers or wires for providing electrical signals or power to the pixels may be arranged in the peripheral area PA.

The display device 2 may have a quadrangular shape, e.g., rectangular shape in which the length in the horizontal direction is greater than the length in the vertical direction, as shown in FIG. 14, but is not limited to this. The display device 2 may have various shapes such as polygonal, circular, or elliptical shapes.

Hereinafter, the display device 2 in an embodiment of the disclosure will be described using an organic light-emitting display device in an embodiment, but the display device of the disclosure is not limited thereto. In another embodiment, a display device of another type, such as a quantum dot light-emitting display, may be used.

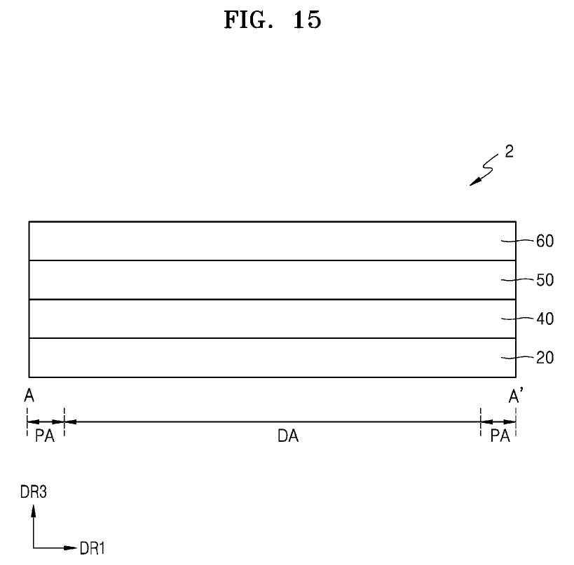

FIG. 15 is a schematic cross-sectional view of an embodiment of a display device of the disclosure. FIG. 15 may correspond to the cross-section taken along line A-A' of FIG. 14.

Referring to FIG. 15, a display device 2 may include a display panel 20, an input sensing layer 40 on the display panel 20, and an optical function layer 50, all of which may be covered by a window 60. The display device 2 may be various types of electronic devices such as a mobile phone, a laptop, or a smart watch.

The display panel 20 may display an image. The display panel 20 may include pixels arranged in a display area DA. The pixels may include display elements and pixel circuits connected thereto. The display element may include an organic light-emitting diode, a quantum dot organic light-emitting diode, or the like.

The input sensing layer 40 may obtain coordinate information corresponding to external input, such as a touch event. The input sensing layer 40 may include sensing electrodes (or touch electrodes) and trace lines connected to the sensing electrodes. The input sensing layer 40 may be disposed over the display panel 20. The input sensing layer 40 may detect external input using a mutual capacitance method or/and a self-capacitance method.

The input sensing layer 40 may be formed directly on the display panel 20, or may be formed separately and then bonded to the display panel 20 using an adhesive layer such as an optical clear adhesive layer. In an embodiment, the input sensing layer 40 may be formed sequentially after the process of forming the display panel 20, in which case the input sensing layer 40 may be understood as part of the display panel 20, and an adhesive layer may not be placed between the input sensing layer 40 and the display panel 20, for example. Although FIG. 15 illustrates that the input sensing layer 40 is interposed between the display panel 20 and the optical function layer 50, in another embodiment, the input sensing layer 40 may be disposed above the optical function layer 50.

The optical function layer 50 may include an anti-reflection layer. The anti-reflection layer may reduce the reflectance of light (external light) incident on the display panel 20 through the window 60. In an embodiment, the anti-reflection layer may include a black matrix and color filters. The color filters may be arranged in consideration of the color of light emitted from each pixel of the display panel 20.

In another embodiment, the anti-reflection layer may include a retarder and a polarizer. The retarder may be of a film type or a liquid crystal coating type. The polarizer may also be of a film type or a liquid crystal coating type. The film type may include a stretchable synthetic resin film, and the liquid crystal coating type may include liquid crystals arranged in a selected array. The retarder and the polarizer may further include protective films. The retarder and polarizer themselves, or the protective films, may be defined as base layers of the anti-reflection layer.

In another embodiment, the anti-reflection layer may include a destructive interference structure. The destructive interference structure may include a first reflective layer and a second reflective layer arranged in different layers. First reflected light and second reflected light respectively reflected from the first reflective layer and the second reflective layer may undergo destructive interference, thereby reducing the reflectance of external light.

In an embodiment, the optical function layer 50 may be formed sequentially after the process of forming the display panel 20 and/or the input sensing layer 40. In an embodiment, an adhesive layer may not be interposed between the optical function layer 50, the display panel 20, and/or the input sensing layer 40.

Although not illustrated in FIG. 15, a layer including an optical clear adhesive or an optical clear resin may be disposed between the window 60 and the optical function layer 50.

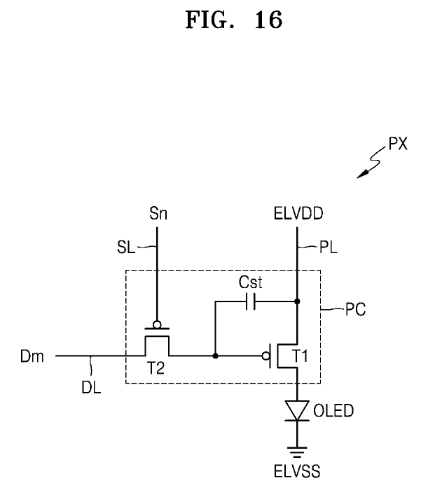

FIG. 16 is an equivalent circuit diagram of an embodiment of a pixel included in a display device of the disclosure.

Referring to FIG. 16, a pixel PX may include an organic light-emitting diode (“OLED”) as a pixel circuit PC and a display element connected to the pixel circuit PC. The pixel circuit PC may include a first thin-film transistor T1, a second thin-film transistor T2, and a storage capacitor Cst. Each pixel PX may emit, through the OLED, light of a predetermined color, e.g., red, green, or blue, or light of red, green, blue, or white.

The second thin-film transistor T2 serves as a switching thin-film transistor and is connected to a scan line SL and a data line DL. Based on a switching signal Sn input from the scan line SL, the second thin-film transistor T2 may transmit a data signal Dm input from the data line DL to the first thin-film transistor T1. The storage capacitor Cst is connected to the second thin-film transistor T2 and a driving voltage line PL, and may store a voltage corresponding to the difference between the voltage received from the second thin-film transistor T2 and the driving voltage ELVDD supplied to the driving voltage line PL.

The first thin-film transistor T1 serves as a driving thin-film transistor, which is connected to the driving voltage line PL and the storage capacitor Cst, and may control a driving current flowing through the OLED from the driving voltage line PL in accordance with a voltage value stored in the storage capacitor Cst. The OLED may emit light having a predetermined luminance according to the driving current. An opposite electrode (e.g., cathode) of the OLED may be supplied with a common voltage ELVSS.

FIG. 16 illustrates that the pixel circuit PC includes two thin-film transistors and one storage capacitor, but the disclosure is not limited to this. The number of thin-film transistors and the number of storage capacitors may be variously changed according to the design of the pixel circuit PC. In an embodiment, the pixel circuit PC may include four, five or more thin-film transistors in addition to the two thin-film transistors described above, for example.

FIG. 17 is a schematic cross-sectional view of an embodiment of a display panel 20 of the disclosure.

Referring to FIG. 17, the display panel 20 may include a substrate 301, a thin-film transistor TR on the substrate 301, and a display element LD on the thin-film transistor TR. The thin-film transistor TR and the display element LD illustrated in FIG. 17 may correspond to the first thin-film transistor T1 and the OLED illustrated in FIG. 16, respectively. The display panel 20 may include an organic light-emitting diode as a display element LD, but is not limited thereto.

The substrate 301 may include glass or polymer resin. In an embodiment, the substrate 301 may have a multilayer structure in which a first layer including a polymer resin and a second layer configured to prevent penetration of external foreign substances are alternately stacked.

The first layer may include a polymer resin such as polyethersulfone (“PES”), polyarylate (“PAR”), polyetherimide (“PEI”), polyethylene naphthalate (“PEN”), polyethylene terephthalate (“PET”), polyphenylene sulfide (“PPS”), polyimide (“PI”), polycarbonate, cellulose triacetate (“TAC”), or cellulose acetate propionate (“CAP”).

The second layer may include an inorganic material such as silicon nitride (SiNₓ) or silicon oxide (SiOₓ).

A buffer layer 302 may be formed on the substrate 301 to prevent impurities from penetrating into a semiconductor layer AP of the thin-film transistor TR. The buffer layer 302 may include an inorganic insulating material such as silicon nitride (SiNₓ), silicon oxynitride (SiON), and silicon oxide (SiOₓ), and may be a single layer or multilayer including the aforementioned inorganic insulating material.

The thin-film transistor TR may be placed on the buffer layer 302. The thin-film transistor TR may include the semiconductor layer AP, a gate electrode GE, a source electrode SE, and a drain electrode DE.

The semiconductor layer AP may include a source region S, a drain region D, and a channel region C between the source region S and the drain region D. The semiconductor layer AP may include polysilicon. In an alternative embodiment, the semiconductor layer AP may include amorphous silicon, an oxide semiconductor, an organic semiconductor, or the like. The gate electrode GE may include a low-resistance metal material. The gate electrode GE may include a conductive material including molybdenum (Mo), aluminum (Al), copper (Cu), titanium (Ti), or the like, and may be formed as a multilayer or single layer including the above materials.

A gate insulating layer 303 between the semiconductor layer AP and the gate electrode GE may include an inorganic insulating material such as silicon oxide (SiOₓ), silicon nitride (SiNₓ), silicon oxynitride (SiON), aluminum oxide (Al₂O₃), titanium oxide (TiOₓ), tantalum oxide (Ta₂O₅), and hafnium oxide (HfO₂). The gate insulating layer 303 may be a single layer or multilayer including the aforementioned materials.

An inter-insulating layer 305 may be placed on the gate electrode GE. The inter-insulating layer 305 may include an inorganic insulating material such as silicon oxide (SiOₓ), silicon nitride (SiNₓ), silicon oxynitride (SiON), aluminum oxide (Al₂O₃), titanium oxide (TiOₓ), tantalum oxide (Ta₂O₅), and hafnium oxide (HfO₂). The inter-insulating layer 305 may be a single layer or multilayer including the aforementioned materials.

The source electrode SE and the drain electrode DE may be placed on the inter-insulating layer 305. The source electrode SE and the drain electrode DE may include a material having good conductivity. The source electrode SE and the drain electrode DE may include a conductive material including molybdenum (Mo), aluminum (Al), copper (Cu), titanium (Ti), etc., and may be formed as a multilayer or single layer including the above materials. In an embodiment, the source electrode SE and the drain electrode DE may be formed in a multilayer structure of Ti/Al/Ti.

A planarization layer 307 may be disposed on the source electrode SE and the drain electrode DE. The planarization layer 307 may include an organic insulating material such as a general-purpose polymer such as polymethylmethacrylate (“PMMA”) or polystylene (“PS”), a polymer derivative having a phenol group, acrylic polymer, an imide-based polymer, an aryl ether-based polymer, an amide-based polymer, a fluorinated polymer, a p-xylene-based polymer, a vinyl alcohol-based polymer, and a blend of these polymers. In an embodiment, the planarization layer 307 may include polyimide. The planarization layer 307 may eliminate a stepped portion caused by the thin-film transistor TR. The surface of the planarization layer 307 facing the display element LD may be a flat surface.

The display element LD electrically connected to the thin-film transistor TR may be placed on the planarization layer 307. The display element LD may include a pixel electrode E1, an intermediate layer EL, and an opposite electrode E2 sequentially stacked on the substrate 301.

The pixel electrode E1 may be placed on the planarization layer 307. The pixel electrode E1 may be electrically connected to the drain electrode DE of the thin-film transistor TR through a contact hole penetrating the planarization layer 307. The pixel electrode E1 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode E1 may include a reflective film including silver (Ag), magnesium (Mg), aluminum (Al), platinum (Pt), palladium (Pd), gold (Au), nickel (Ni), neodymium (Nd), iridium (Ir), chromium (Cr), or any combinations thereof. In another embodiment, the pixel electrode E1 may further include a film including or consisting of ITO, IZO, ZnO or In₂O₃ above and/or below the reflective film described above.

A pixel-defining layer 309 may be disposed on the pixel electrode E1. The pixel-defining layer 309 may define an emission area by defining an opening corresponding to the pixel, that is, an opening that exposes at least the central portion of the pixel electrode E1. When viewed in a direction (direction DR3) substantially perpendicular to the substrate 301, the pixel-defining layer 309 may overlap the edge of the pixel electrode E1. The pixel-defining layer 309 may include an inorganic insulating material such as silicon nitride (SiNₓ), silicon oxynitride (SiON), or silicon oxide (SiOₓ). The pixel electrode E1 may serve as an anode electrode.

The intermediate layer EL may include a relatively low molecular-weight or relatively high molecular-weight material. When including a relatively low molecular-weight material, the intermediate layer EL may have a structure in which a hole injection layer, a hole transport layer, an emission layer, an electron transport layer, and an electron injection layer are stacked in a single or composite structure, and may include various organic materials including copper phthalocyanine (CuPc), N,N-di(naphthalene-1-yl)-N,N'-diphenyl-benzidine (“NPB”), tris-8-hydroxyquinoline aluminum (Alq₃), or the like. These layers may be formed by vacuum deposition.

When the intermediate layer EL includes a polymer material, the intermediate layer EL may have a structure including a hole transport layer HTL and an emission layer EML. In an embodiment, the hole transport layer HTL may include poly(3,4-ethylenedioxythiophene) (“PEDOT”), and the emission layer EML may include a polyphenylenevinylene (“PPV”)-based material and a polyfluorene-based material. The structure of the intermediate layer EL is not limited to the above and may have various structures. In an embodiment, the intermediate layer EL may be provided in plural so that a plurality of intermediate layers EL may be respectively arranged on the plurality of pixel electrodes E1. In an embodiment, at least one of the layers constituting the intermediate layer EL may be integrally formed (or unitary) across the plurality of pixel electrodes E1, for example. In an alternative embodiment, the intermediate layer EL may include a patterned layer corresponding to each of the plurality of pixel electrodes E1.

The opposite electrode E2 may serve as a cathode electrode. The opposite electrode E2 may be a transmissive electrode or a reflective electrode. In an embodiment, the opposite electrode E2 may be a transparent or semi-transparent electrode and may include or consist of a relatively low work function metal thin-film including Li, Ca, LiF/Ca, LiF/Al, Al, Ag, Mg, or any combinations thereof. The opposite electrode E2 may be disposed across the plurality of pixels and may serve as a common electrode of the display panel 20.

The pixel electrode E1, the intermediate layer EL, and the opposite electrode E2 may form the display element LD. The display element LD may emit light based on the driving current transmitted from the thin-film transistor TR .

The display device 2 in the embodiment of the disclosure may be applied to various electronic devices. The electronic device in an embodiment includes the display device 2 described above, and may further include other modules or devices having additional functions, in addition to the display device 2.

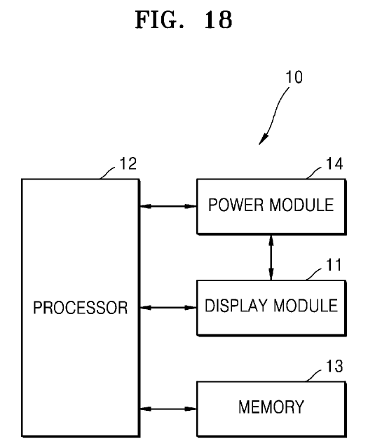

FIG. 18 is a block diagram illustrating an embodiment of an electronic device 10 of the disclosure.

Referring to FIG. 18, an electronic device 10 in an embodiment of the disclosure may include a display module 11, a processor 12, a memory 13, and a power module 14.

The processor 12 may include at least one of a central processing unit (“CPU”), an application processor (“AP”), a graphics processing unit (“GPU”), a communication processor (“CP”), an image signal processor (“ISP”), and a controller.

Data information desired for the operation of the processor 12 or display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module that converts power supplied by the power supply module to generate power desired for the operation of the electronic device 10.

At least one of the components of the above-described electronic device 10 may be included in the display device in the embodiments described above. Additionally, some individual modules that are functionally included in a single module may be partially included in the display device, while others may be provided separately from the display device. In an embodiment, the display device may include the display module 11, while the processor 12, the memory 13, and the power module 14 may be provided as other devices within the electronic device 10, rather than within the display device, for example.

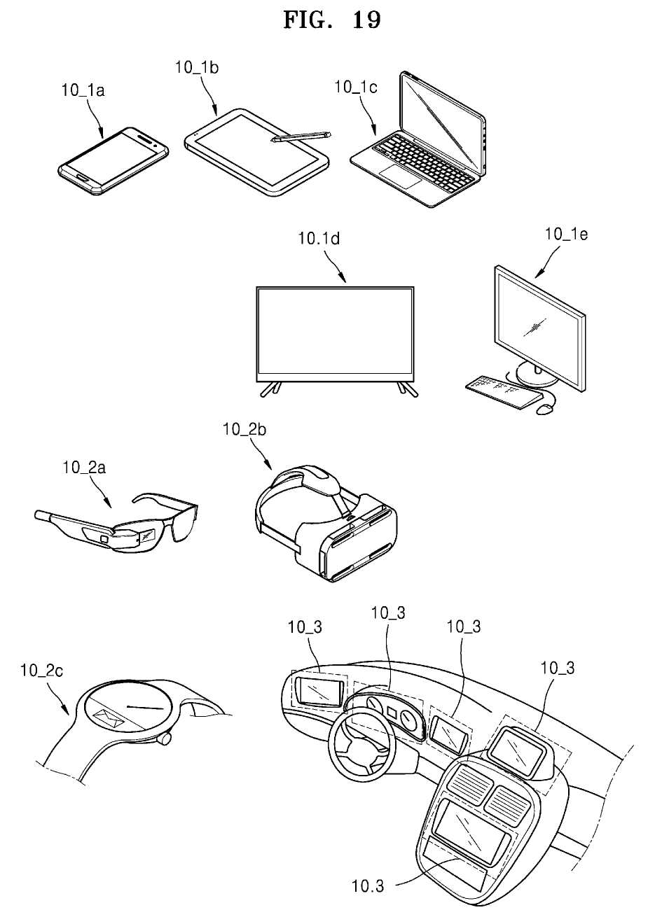

FIG. 19 illustrates schematic diagrams of embodiments of electronic devices.

Referring to FIG. 19, various electronic devices to which display devices in embodiments are applied may include not only image display electronic devices such as a smart phone 10_1a, a tablet personal computer 10_1b, a laptop computer 10_1c, a television (“TV”) 10_1d, and a desk monitor 10_1e, but also wearable electronic devices including a display module, such as smart glasses 10_2a, a head disposed (e.g., mounted) display 10_2b, and a smart watch 10_2c, and vehicle electronic devices 10_3 including a display module, such as a room mirror display, and a center information display (“CID”) disposed on an instrument panel, a center fascia, or a dashboard of a vehicle.

By embodiments of the disclosure, shadow defects caused by a deposition mask may be reduced, and deposition efficiency and deposition precision may be improved.

In addition, by embodiments of the disclosure, it is easy to manufacture a high-resolution organic light-emitting display device, and reliability may be improved by improving PPA.

The scope of the disclosure is not limited by these effects, and may be expanded in various ways without departing from the spirit and scope of the disclosure.

Although the disclosure has been described with reference to the embodiments illustrated in the drawings, these embodiments are merely exemplary. One of ordinary skill in the art will understand that various modifications and equivalent embodiments will be apparent from this description. Accordingly, the inventive concept is not limited to such embodiments, but rather to the broader scope of the presented claims and various obvious modifications and equivalent arrangements.

What is claimed is:

1. A deposition mask comprising:
a mask substrate in which an opening is defined; and
a mask pattern disposed on the mask substrate, the mask pattern comprising:
a first insulating layer disposed on the mask substrate; and
a second insulating layer disposed on the first insulating layer,
wherein a plurality of hole patterns which overlap the opening and penetrate through the first insulating layer and the second insulating layer is defined in the mask pattern, and
a cross-section of the mask pattern has a reverse taper shape of which a width in a first direction increases from a rear surface of the mask pattern, the rear surface being disposed next to the mask substrate, toward a top surface of the mask pattern opposite to the rear surface.

2. The deposition mask of claim 1,
wherein the second insulating layer is formed by a deposition process different from a deposition process used to form the first insulating layer.

3. The deposition mask of claim 1,
wherein the second insulating layer is deposited at a higher temperature than a temperature for the first insulating layer.

4. The deposition mask of claim 1,
wherein the first insulating layer is deposited by plasma-enhanced chemical vapor deposition, and
the second insulating layer is deposited by low-pressure chemical vapor deposition.

5. The deposition mask of claim 1,
wherein a density of the first insulating layer is lower than a density of the second insulating layer.

6. The deposition mask of claim 1,
wherein an etch rate of the first insulating layer is greater than an etch rate of the second insulating layer.

7. The deposition mask of claim 1,
wherein the first insulating layer or the second insulating layer comprises silicon nitride (SiNₓ).

8. The deposition mask of claim 1,
wherein the mask pattern further comprises at least one of a first carbon layer between the first insulating layer and the second insulating layer or a second carbon layer on the second insulating layer.

9. The deposition mask of claim 8,
wherein the first carbon layer or the second carbon layer comprises amorphous carbon.

10. The deposition mask of claim 8,
wherein the first carbon layer or the second carbon layer has a thickness less than a thickness of the first insulating layer.

11. A method of manufacturing a deposition mask, the method comprising: forming a first preliminary insulating layer on a preliminary mask substrate;
forming a second preliminary insulating layer on the first preliminary insulating layer;
defining a plurality of hole patterns penetrating through the first preliminary insulating layer and the second preliminary insulating layer; and
defining an opening in the preliminary mask substrate, the opening overlapping the plurality of hole patterns,
wherein a cross-section of each of the plurality of hole patterns has a positive taper shape of which a width in a first direction decreases from the first preliminary insulating layer toward the second preliminary insulating layer.

12. The method of claim 11,
wherein the forming the second preliminary insulating layer is performed using a deposition process different from a deposition process used for the forming the first preliminary insulating layer.

13. The method of claim 12,
wherein the first preliminary insulating layer is deposited by plasma-enhanced chemical vapor deposition and
the second preliminary insulating layer is deposited by low-pressure chemical vapor deposition.

14. The method of claim 11,
wherein the forming the second preliminary insulating layer and the forming the first preliminary insulating layer are performed using a same deposition process.

15. The method of claim 11,
wherein the first preliminary insulating layer and the second preliminary insulating layer are selectively etched by a same etching material, and
an etch rate of the first preliminary insulating layer with respect to the etching material is greater than an etch rate of the second preliminary insulating layer with respect to the etching material.

16. The method of claim 11,
wherein the first preliminary insulating layer or the second preliminary insulating layer includes silicon nitride (SiNₓ).

17. The method of claim 11, further comprising,
prior to the forming the second preliminary insulating layer,
forming a preliminary carbon layer on the first preliminary insulating layer,
wherein the forming the plurality of hole patterns comprises selectively etching the first preliminary insulating layer, the preliminary carbon layer, and the second preliminary insulating layer to form the plurality of hole patterns.

18. The method of claim 11, further comprising,
prior to the forming the plurality of hole patterns,
forming a preliminary carbon layer on the second preliminary insulating layer,
wherein the forming the plurality of hole patterns comprises selectively etching the first preliminary insulating layer, the preliminary carbon layer, and the second preliminary insulating layer to form the plurality of hole patterns.

19. The method of claim 11, further comprising,
prior to the forming the second preliminary insulating layer, forming a first preliminary carbon layer on the first preliminary insulating layer; and
prior to the forming the plurality of hole patterns, forming a second preliminary carbon layer on the second preliminary insulating layer,
wherein the forming the plurality of hole patterns comprises selectively etching the first preliminary insulating layer, the first preliminary carbon layer, the second preliminary insulating layer, and the second preliminary carbon layer to form the plurality of hole patterns.

20. An electronic device comprising:
a substrate;
a plurality of thin-film transistors arranged on the substrate;
a plurality of pixel electrodes electrically connected to a thin-film transistor of the plurality of thin-film transistors;
a plurality of intermediate layers arranged on the plurality of pixel electrodes; and
an opposite electrode disposed on the plurality of intermediate layers,
wherein at least one of the plurality of thin-film transistors, the plurality of pixel electrodes, the plurality of intermediate layers, or the opposite electrode is formed using a deposition mask comprising:
a mask substrate in which an opening is defined; and
a mask pattern disposed on the mask substrate, the mask pattern comprising:
a first insulating layer disposed on the mask substrate; and
a second insulating layer disposed on the first insulating layer,
wherein a plurality of hole patterns which overlap the opening and penetrate through the first insulating layer and the second insulating layer is defined in the mask pattern, and
a cross-section of the mask pattern has a reverse taper shape of which a width in a first direction increases from a rear surface of the mask pattern, the rear surface being disposed next to the mask substrate, toward a top surface of the mask pattern opposite to the rear surface.
